(19) United States
(12) Patent Application Publication
(10) Pub. No.: US 2025/0372566 A1
(43) Pub. Date: Dec. 4, 2025

(54) SEMICONDUCTOR PACKAGES AND METHOD FOR FABRICATING THE SAME

(71) Applicant: Samsung Electronics Co., Ltd., Suwon-si (KR)

(72) Inventor: Youngbae KIM, Suwon-si (KR)

(73) Assignee: Samsung Electronics Co., Ltd., Suwon-si (KR)

(21) Appl. No.: 18/980,655

(22) Filed: Dec. 13, 2024

(30) Foreign Application Priority Data
May 30, 2024 (KR) 10-2024-0070728

(51) Int. Cl. H01L 23/00; H01L 25/00; H01L 25/07

(52) U.S. Cl. CPC H01L 24/48; H01L 24/24; H01L 24/73; H01L 25/074; H01L 25/50; H01L 2224/24146; H01L 2224/244; H01L 2224/48108; H01L 2224/48227; H01L 2224/48491; H01L 2224/73227; H01L 2225/0651; H01L 2225/06562

(57) ABSTRACT

A semiconductor package includes a semiconductor stack including first to Nth semiconductor dies (where N is a natural number of 2 or more), each of the first to Nth semiconductor dies including a plurality of connection pads on the first surface, the first to Nth semiconductor dies being sequentially stacked so that the plurality of connection pads are exposed, and a plurality of vertical wires on each of the first to Nth semiconductor dies, each of the plurality of vertical wires being connected to a corresponding one of the plurality of connection pads, wherein each of the plurality of vertical wires include a plurality of bonding pads stacked on each of the plurality of connection pads and a wire on the plurality of bonding pads.

### CROSS-REFERENCE TO RELATED APPLICATION

This application claims priority to and the benefit of Korean Patent Application No. 10-2024-0070728 filed in the Korean Intellectual Property Office on May 30, 2024, the entire contents of which are incorporated herein by reference.

### BACKGROUND

### (a) Field

The present disclosure relates to semiconductor packages and methods of manufacturing the same.

### (b) Description of the Related Art

The Fan-out Wafer Level Package FOWLP is a package technology that mounts a semiconductor die on a wafer and extends the input/output terminal region under the wafer to the fan-out region of the semiconductor die. According to the fan-out wafer level package (FOWLP), the number of input/output terminals placed under the wafer can be increased, so that all connections to input/output terminals of semiconductor dies with finer intervals due to the miniaturization and/or higher integration of semiconductor dies can be made possible, the pattern of wiring can be refined by applying Redistribution Layer (RDL) technology, the thickness of the package can be reduced because the printed circuit board (PCB) is not used, and the heat dissipation function can also be improved.

Such a fan-out wafer level package FOWLP improves its function and/or performance as more semiconductor dies are mounted on a wafer. However, if many semiconductor dies are mounted on a wafer, it may be difficult to design the connection between the wafer and the semiconductor dies according to the stacking structure of the semiconductor dies, making it difficult to efficiently connect the input/output terminals of each semiconductor die to the wafer.

To solve these problems and implement a fan-out wafer level package FOWLP with many semiconductor dies on a wafer, vertical wire technology is being studied. A vertical wire is a straight line implementation of a wiring through which a signal or power is routed. Manufacturing a fan-out wafer level package (FOWLP) using vertical wires may improve the signal integrity (SI) and/or power integrity (PI) of the semiconductor package, and reduce or minimize the size of the semiconductor package. On the other hand, when vertical wires are used, vertical wires may be broken or displaced in the molding process, and due to errors between the spacing of connection members connected to vertical wires and the stacking tolerance of semiconductor dies, connection failure may occur between vertical wires and connection members.

### SUMMARY

Semiconductor packages and methods for manufacturing a semiconductor package may be provided, wherein the semiconductor package includes vertical wires connecting each of first to Nth semiconductor dies (where N is a natural number greater than or equal to 2) to the redistribution structure, and each of the vertical wires includes stacked bonding pads and a wire on the bonding pads.

Semiconductor packages and semiconductor package manufacturing methods applied by changing the arrangement and number of bonding pads on each of first to Nth semiconductor dies according to the stacking structure of the first to Nth semiconductor dies may be provided.

A semiconductor package according to an example embodiment includes a semiconductor stack including first to Nth semiconductor dies (where N is a natural number of 2 or more), each of the first to Nth semiconductor dies including a plurality of connection pads on the first surface, the first to Nth semiconductor dies being sequentially stacked so that the plurality of connection pads are exposed, and a plurality of vertical wires on each of the first to Nth semiconductor dies, each of the plurality of vertical wires being connected to a corresponding one of the plurality of connection pads, wherein each of the plurality of vertical wires may include a plurality of bonding pads stacked on each of the plurality of connection pads; and a wire on the plurality of bonding pads.

A semiconductor package according to an example embodiment includes a semiconductor stack including a first to Nth semiconductor dies (where N is a natural number of 2 or more), each of the first to Nth semiconductor dies including a plurality of connection pads on the first surface, the first to Nth semiconductor dies being sequentially stacked so that the plurality of connection pads are exposed, a plurality of vertical wires on each of the first to N−1th semiconductor dies, each of the plurality of vertical wires being connected to a corresponding one of the plurality of connection pads, a molding member covering the first to Nth semiconductor dies and the plurality of vertical wires, a redistribution structure on the molding member, and a plurality of connection members on the redistribution structure, wherein each of the plurality of vertical wires may include a plurality of bonding pads stacked on each of the plurality of connection pads; and a wire on the plurality of bonding pads.

A semiconductor package manufacturing method according to an example embodiment includes sequentially stacking, on a carrier, first to N semiconductor dies each including a plurality of connection pads on a first surface thereof such that the plurality of connection pads are exposed, where N is a natural number greater than or equal to 2, and forming a plurality of vertical wires on the first to Nth semiconductor dies. The forming the plurality of vertical wires on the first to Nth semiconductor dies includes stacking a plurality of bonding pads on each of the plurality of connection pads and vertically forming a wire on the plurality of bonding pads.

In the vertical wire connecting the semiconductor die to the redistribution structure, the wire is fixed with a plurality of bonding pads to reduce or prevent a short circuit between wires and/or reduce the bending stress generated on the wire, thereby a wire may not be broken or displaced by the pressure of a molding material or member supplied in a subsequent molding process (e.g., a compression or transfer molding process).

By arranging a plurality of bonding pads under the wire, it is possible to reduce the aspect ratio of the vertical wire and/or reduce the alignment error between the vertical wire and the connection member connected to the vertical wire.

Additionally, the alignment error between the vertical wire and the connection member connected to the vertical wire on the upper semiconductor die is less than the alignment error between the vertical wire and the connection member connected to the vertical wire on the lower semiconductor die. Therefore, it is possible to secure more predictable design margins and/or process margins for the fan-out wafer level package FOWLP by applying vertical wires with multiple bonding pads under the wires to the first to Nth semiconductor dies stacked in a step structure, thereby solving the connection problem that occurs when multiple semiconductor dies are placed in the fan-out wafer level package FOWLP.

### BRIEF DESCRIPTION OF THE DRAWINGS

FIG. 1 is a cross-sectional view illustrating a semiconductor package according to an example embodiment.

FIG. 2 is a plan view illustrating a semiconductor die and bonding pads of the semiconductor package of FIG. 1.

FIG. 3 is a cross-sectional view illustrating a semiconductor package according to an example embodiment.

FIG. 4 is a cross-sectional view illustrating a semiconductor package according to an example embodiment.

FIG. 5 is a cross-sectional view illustrating a semiconductor package according to an example embodiment.

FIGS. 6 to 21 are cross-sectional views illustrating a method for manufacturing the semiconductor package of FIG. 1.

### DETAILED DESCRIPTION

Hereinafter, various example embodiments of the present disclosure will be described in detail with reference to the accompanying drawings so that those skilled in the art may easily implement the present disclosure. The present disclosure may be implemented in several different forms and is not limited to the example embodiments described herein.

In order to clearly describe the present disclosure in the drawings, parts unrelated to the description are omitted, and the same reference numerals are attached to the same or similar components throughout the specification.

In addition, the size and thickness of each component shown in the drawing are arbitrarily shown for better understanding and ease of description, so the present disclosure is not necessarily limited to what is shown.

Throughout this specification, when a part is “connected” to another element, it may include not only being “directly connected” but also being “indirectly connected” with other members in between. In addition, when a part “includes” or “comprises” a component throughout the specification, this means other components may be further included, rather than excluding other components unless otherwise stated.

Additionally, when a part of a layer, film, region, substrate, etc. is referred to be “above” or “on” another part, this may include not only cases where it is “directly on” another part, but also cases where there are intervening elements in between. In contrast, when a part is referred to be “directly on” another part, it means that there are no intervening elements in between. In addition, being “above” or “on” a reference part means being positioned above or below the reference part, and does not necessarily mean being positioned “above” or “on” it in the opposite direction of gravity.

In addition, throughout the specification, when it comes to “on a plane,” it means when the target part is viewed from above, and when it comes to “cross-section,” it means when the cross-section of the target part is vertically cut from the side.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

Hereinafter, semiconductor packages and method of manufacturing the semiconductor packages according to an example embodiment will be described with reference to the drawings.

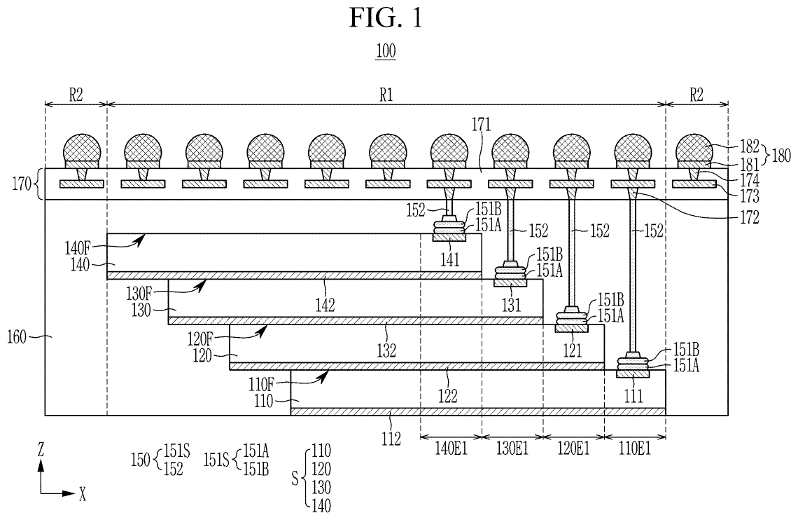

FIG. 1 is a cross-sectional view illustrating a semiconductor package 100 according to an example embodiment.

Referring to FIG. 1, the semiconductor package 100 may include a semiconductor stack S, vertical wires 150, a molding material 160, a redistribution structure 170, and a connection structure 180. In an example embodiment, the semiconductor package 100 may be a semiconductor package manufactured based on a Fan-out Wafer Level Package FOWLP or a Fan-out Panel Level Package FOPLP technology.

The semiconductor stack S may include first to Nth semiconductor dies (where N is a natural number of 2 or more). Each of the first to Nth semiconductor dies includes connection pads on the active surface. The first to Nth semiconductor dies are sequentially stacked so that the connection pads are exposed.

The function and/or performance of the semiconductor package 100 are improved as the semiconductor stack S includes a larger number of semiconductor dies. However, if a semiconductor stack(S) is formed with too many semiconductor dies, variables such as the aspect ratio of vertical wire 150 that affects the sweep of vertical wire 150, the bonding strength of the material used in vertical wire 150, and the alignment error between vertical wire 150 and connection member 182 connected to vertical wire 150 will cause problems such as difficulty in designing the connection between redistribution structure 170 and semiconductor dies in line with the stacking structure of semiconductor dies. Therefore, N, a number of semiconductor dies, may be determined in consideration of the function and/or performance of the semiconductor package 100, and the connection between the redistribution structure 170 and the semiconductor dies. Although, in the drawings according to the present disclosure, a semiconductor stack S with N equal to 4 is illustrated, it is not limited to thereto and a semiconductor stack S including fewer or more semiconductor dies may be included in the present disclosure.

In an example embodiment, the semiconductor stack S may include first to fourth semiconductor dies (110, 120, 130, 140) and first to fourth adhesive members (112, 122, 132, 142). The first to fourth adhesive members (112, 122, 132, 142) are disposed alternately with the first to fourth semiconductor dies (110, 120, 130, 140).

The first semiconductor die 110 has an active surface 110F. The active surface may be referred to as the first surface. The active surface 110F is positioned toward the redistribution structure 170. The first semiconductor die 110 may include a semiconductor device such as a memory cell array, a transistor, a capacitor, an inductor, or a resistor on the active surface 110F. In an example embodiment, the first semiconductor die 110 may include a volatile or nonvolatile memory die.

The first semiconductor die 110 includes first connection pads 111 on the active surface 110F. The first connection pads 111 are positioned on the first edge region 110E1 of the first semiconductor die 110. The first edge region 110E1 of the first semiconductor die 110 is defined as a portion not covered by the second semiconductor die 120 on the active surface 110F of the first semiconductor die 110. Each of the first connection pads 111 electrically connects each of the bonding pads 151 of the vertical wire 150 to the semiconductor device of the first semiconductor die 110. In an example embodiment, the first connection pads 111 may include at least one of copper, nickel, zinc, gold, silver, platinum, palladium, chromium, titanium, or alloys thereof.

The first adhesive member 112 may be disposed on at least a portion of a surface opposite to the active surface 110F of the first semiconductor die 110. The opposite side may be referred to as the second surface. In an example embodiment, the first adhesive member 112 may include a die attach film DAF. The first adhesive member 112 may be exposed to the outside from the molding member 160. In another example embodiment, the first adhesive member 112 may not be present on the opposite side of the active surface 110F of the first semiconductor die 110, and in this case, the opposite side of the active surface 110F of the first semiconductor die 110 may be exposed to the outside from the molding member 160.

The second semiconductor die 120 is disposed on the first semiconductor die 110 in the Z direction (e.g., vertical direction). The second semiconductor die 120 is disposed to have an offset in the X direction (e.g., first horizontal direction) from the adjacent first semiconductor die 110. By this offset, the first connection pads 111 of the first semiconductor die 110 are exposed, and each of the first connection pads 111 may be connected to a corresponding one of the vertical wires 150.

The second semiconductor die 120 has an active surface 120F. The active surface 120F is positioned toward the redistribution structure 170. The second semiconductor die 120 may include a semiconductor device such as a memory cell array, a transistor, a capacitor, an inductor, or a resistor on the active surface 120F. In an example embodiment, the second semiconductor die 120 may include a volatile or nonvolatile memory die.

The second semiconductor die 120 may include second connection pads 121 on the active surface 120F. The second connection pads 121 are positioned on the first edge region 120E1 of the second semiconductor die 120. The first edge region 120E1 of the second semiconductor die 120 is defined as a portion not covered by the third semiconductor die 130 on the active surface 120F of the second semiconductor die 120. Each of the second connection pads 121 electrically connects a corresponding one of the bonding pads 151 of the vertical wire 150 to the semiconductor device of the second semiconductor die 120. In an example embodiment, the second connection pads 121 may include at least one of copper, nickel, zinc, gold, silver, platinum, palladium, chromium, titanium, or alloys thereof.

The second adhesive member 122 may be disposed on at least a portion of a surface opposite to the active surface 120F of the second semiconductor die 120. The second adhesive member 122 attaches the second semiconductor die 120 to the first semiconductor die 110. In an example embodiment, the second adhesive member 122 may include a die attach film DAF.

The third semiconductor die 130 is disposed on the second semiconductor die 120 in the z-direction (e.g., vertical direction). The third semiconductor die 130 may be disposed to have an offset in the X-direction (e.g., the first horizontal direction) from the adjacent second semiconductor die 120. By this offset, the second connection pads 121 of the second semiconductor die 120 may be exposed, and each of the second connection pads 121 may be connected to a corresponding one of the vertical wires 150.

The third semiconductor die 130 has an active surface 130F. The active surface 130F is positioned toward the redistribution structure 170. The third semiconductor die 130 may include a semiconductor device such as a memory cell array, a transistor, a capacitor, an inductor, or a resistor on the active surface 130F. In an example embodiment, the third semiconductor die 130 may include a volatile or nonvolatile memory die.

The third semiconductor die 130 includes third connection pads 131 on the active surface 130F. The third connection pads 131 are positioned on the first edge region 130E1 of the third semiconductor die 130. The first edge region 130E1 of the third semiconductor die 130 is defined as a portion not covered by the fourth semiconductor die 140 on the active surface 130F of the third semiconductor die 130. Each of the third connection pads 131 electrically connects a corresponding one of the bonding pads 151 of the vertical wire 150 to the semiconductor device of the third semiconductor die 130. In an example embodiment, the third connection pads 131 may include at least one of copper, nickel, zinc, gold, silver, platinum, palladium, chromium, titanium, or alloys thereof.

The third adhesive member 132 may be disposed on at least a portion of a surface opposite to the active surface 130F of the third semiconductor die 130. The third adhesive member 132 attaches the third semiconductor die 130 to the second semiconductor die 120. In an example embodiment, the third adhesive member 132 may include a die attach film DAF.

The fourth semiconductor die 140 is disposed on the third semiconductor die 130 in the Z direction (vertical direction). The fourth semiconductor die 140 is disposed to have an offset in the X direction (first horizontal direction) from the adjacent third semiconductor die 130. By this offset, the third connection pads 131 of the third semiconductor die 130 are exposed, and each of the third connection pads 131 may be connected to each of the vertical wires 150.

The fourth semiconductor die 140 has an active surface 140F. The active surface 140F is positioned toward the redistribution structure 170. The fourth semiconductor die 140 may include a semiconductor device such as a transistor, a capacitor, an inductor, or a resistor on the active surface 140F. In an example embodiment, the fourth semiconductor die 140 may include a logic die.

The fourth semiconductor die 140 includes fourth connection pads 141 on the active surface 140F. The fourth connection pads 141 may be positioned on the first edge region 140E1 of the fourth semiconductor die 140, but are not limited thereto. The first edge region 140E1 of the fourth semiconductor die 140 may be defined as a region from the side surface of the fourth semiconductor die 140 to a desired (or alternatively, predetermined) distance. The first edge region 140E1 of the fourth semiconductor die 140 may be defined as a region of the fourth semiconductor die 140 corresponding to a region in which each of the first edge regions (110E1, 120E1, 130E1, 140E1) is positioned in each of the first to fourth semiconductor dies (110, 120, 130, 140). Each of the fourth connection pads 141 electrically connects a corresponding one of the bonding pads 151 of the vertical wire 150 to the semiconductor device of the fourth semiconductor die 140. In an example embodiment, the fourth connection pads 141 may include at least one of copper, nickel, zinc, gold, silver, platinum, palladium, chromium, titanium, or alloys thereof.

The fourth adhesive member 142 may be disposed on at least a portion of a surface opposite to the active surface 140F of the fourth semiconductor die 140. The fourth adhesive member 142 attaches the fourth semiconductor die 140 to the third semiconductor die 130. In an example embodiment, the fourth adhesive member 142 may include a die attach film DAF.

The vertical wires 150 are disposed on the first to fourth semiconductor dies (110, 120, 130, 140). The vertical wires 150 are straight lines implementation of wires through which a signal or power is routed. Each of the vertical wires 150 is disposed between a corresponding one of the first to fourth connection pads (111, 121, 131, 141) and a corresponding one of the first redistribution vias 172 of the redistribution structure 170. Each of the vertical wires 150 electrically connects a corresponding one of the first redistribution vias 172 of the redistribution structure 170 to a corresponding one of the first to fourth connection pads (111, 121, 131, 141). By connecting the semiconductor stack S and the redistribution structure 170 using vertical wires 150 in the fan-out wafer level package FOWLP, a path through which a signal or power is routed may be shortened. Accordingly, signal integrity SI and power integrity PI of the semiconductor package 100 may be increased, and the size of the semiconductor package may be reduced or minimized.

The vertical wire 150 may include a bonding pad stack 151S and a wire 152. The bonding pad stack 151S is disposed on each of the first to fourth connection pads (111, 121, 131, 141). The bonding pad stack 151S may include bonding pads 151 which are stacked. The bonding pad stack 151S may include first to Mth bonding pads (where M is a natural number of two or more) stacked in the Z direction (vertical direction). M may be determined in consideration of variables such as the distance between each of the first to Nth semiconductor dies and the redistribution structure 170, the length of the vertical wire 150, the aspect ratio of the vertical wire 150 affecting the sweep of the vertical wire 150, the bonding strength of the material used in the vertical wire 150, and the alignment error between the vertical wire 150 and the connection member 182 connected to the vertical wire 150. In FIG. 1 according to the present disclosure, a bonding pad stack 151S in which M is 2 is illustrated, but the present disclosure is not limited thereto, and a bonding pad stack 151S including fewer or more bonding pads may be included in the present disclosure. In an example embodiment, the bonding pad stack 151S may include a first bonding pad 151A and a second bonding pad 151B on the first bonding pad 151A. In an example embodiment, each of the vertical wires 150 may include one bonding pad 151. In an example embodiment, the number of bonding pads 151 included in each of the vertical wires 150 may be the same across the vertical wires 150. In an example embodiment, the first to Mth bonding pads may include at least one of gold, silver, copper, lead, platinum, or alloys thereof.

The wire 152 extends in the Z direction (vertical direction) on the bonding pad stack 151S. The wire 152 is disposed between the Mth bonding pad of the bonding pad stack 151S (the second bonding pad 151B in FIG. 1; The uppermost bonding pad among the bonding pads) and a corresponding one of the first redistribution vias 172 of the redistribution structure 170. The wire 152 electrically connects each of the first redistribution vias 172 of the redistribution structure 170 to the Mth bonding pad (the second bonding pad 151B in FIG. 1) corresponding thereto. In an example embodiment, the wire 152 may include at least one of gold, silver, copper, lead, platinum, or alloys thereof. In an example embodiment, each of the vertical wires 150 on the first semiconductor die 110 may have an aspect ratio of the diameter of the wire 152 to the height of the vertical wire 150 of about 1:5 to about 1:15.

According to the present disclosure, it is possible to improve resistance to bending stress applied to the wire 152 in the process after the wire bonding process by fixing (for example, strongly) the wire 152 with the bonding pad stack 151S including a plurality of bonding pads. Accordingly, a short circuit between the wires 152 may be reduced or prevented and the wire 152 may not be broken or displaced by the pressure of a molding material or member supplied in a subsequent molding process (e.g., a compression or transfer molding process). In addition, by arranging a bonding pad stack 151S including a plurality of bonding pads, the aspect ratio of vertical wire 150 may be reduced, and the alignment error between a vertical wire 150 and a connection member 182 connected to the vertical wire 150 may be reduced.

The molding member 160 covers the semiconductor stack S and the vertical wires 150. The molding member 160 protects the semiconductor stack S and the vertical wires 150 from an external environment, thereby securing electrical or mechanical stability of the semiconductor package 100.

The redistribution structure 170 is disposed on the molding member 160 and on the vertical wires 150. The redistribution structure 170 is spaced apart from the Nth semiconductor die (the fourth semiconductor die 140 in FIG. 1) in the Z direction (vertical direction). The redistribution structure 170 may include a dielectric 171, first redistribution vias 172 in the dielectric 171, redistribution lines 173, and second redistribution vias 174. In other example embodiments, a redistribution structure 170 comprising fewer or more redistribution lines and redistribution vias may be included in the scope of the present disclosure.

The dielectric 171 protects and insulates the first redistribution vias 172, the redistribution lines 173, and the second redistribution vias 174. A connection structure 180 is disposed on the upper surface of the dielectric 171. The molding member 160 and the vertical wires 150 are disposed on the lower surface of the dielectric 171.

Each of the first redistribution vias 172 is disposed between a corresponding one of the vertical wires 150 and a corresponding one of the redistribution lines 173. Each of the first redistribution vias 172 electrically connects a corresponding one of the redistribution lines 173 to a corresponding one of the vertical wires 150 in the Z direction (vertical direction). Each of the redistribution lines 173 is disposed between a corresponding one of the first redistribution vias 172 and a corresponding one of the second redistribution vias 174. Each of the redistribution lines 173 extends in the horizontal direction and electrically connects a corresponding one of the first redistribution vias 172 and a corresponding one of the second redistribution vias 174 in the vertical direction. Some of the redistribution lines 173 electrically connect some of the vertical wires 150 in the fan-in region to some of the connection members 182 in the fan-out region, respectively. Each of the second redistribution vias 174 is disposed between a corresponding one of the redistribution lines 173 and a corresponding one of the conductive pads 181. Each of the second redistribution vias 174 electrically connects a corresponding one of the conductive pads 181 to a corresponding one of the redistribution lines 173.

The connection structure 180 is disposed on the upper surface of the redistribution structure 170. The connection structure 180 may include conductive pads 181 and connection members 182. The conductive pads 181 and the connection members 182 are disposed in the fan-in region and the fan-out region. Each of the conductive pads 181 electrically connects a corresponding one of the second redistribution vias 174 of the redistribution structure 170 to a corresponding one of the connection members 182. Each of the connection members 182 is disposed on a corresponding one of the conductive pads 181. The connection members 182 electrically connect the semiconductor package 100 to an external device (not shown). The connection members 182 of the fan-out region may be electrically connected to the first to Nth semiconductor dies in the fan-in region through the conductive pads 181, the second redistribution vias 174, the redistribution lines 173, the first redistribution vias 172, and the vertical wires 150.

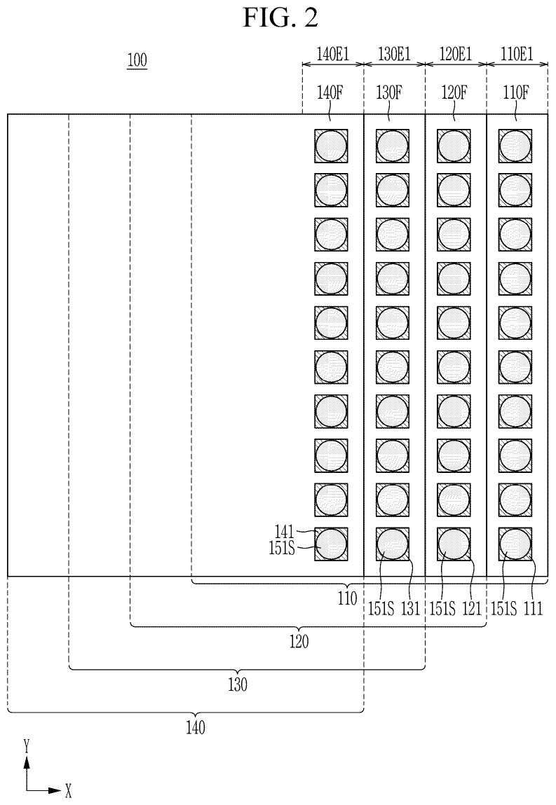

FIG. 2 is a plan view illustrating first to fourth semiconductor dies (110, 120, 130, 140) and bonding pads 151 of the semiconductor package 100 of FIG. 1.

Referring to FIG. 2, the first connection pads 111 are disposed on the first edge region 110E1 of the active surface 110F of the first semiconductor die 110. Each of the bonding pad stacks 151S on the first semiconductor die 110 is disposed on a corresponding one of the first connection pads 111. The first connection pads 111 and the bonding pad stacks 151S on the first semiconductor die 110 are arranged in a line in the Y direction (second horizontal direction) on the first edge region 110E1.

The second connection pads 121 are disposed on the first edge region 120E1 of the active surface 120F of the second semiconductor die 120. Each of the bonding pad stacks 151S on the second semiconductor die 120 is disposed on each of the second connection pads 121. The second connection pads 121 and the bonding pad stacks 151S on the second semiconductor die 120 are arranged in a line in the Y direction (second horizontal direction) on the first edge region 120E1.

The third connection pads 131 are disposed on the first edge region 130E1 of the active surface 130F of the third semiconductor die 130. Each of the bonding pad stacks 151S on the third semiconductor die 130 is disposed on each of the third connection pads 131. The third connection pads 131 and the bonding pad stacks 151S on and the third semiconductor die 130 are arranged in a row in the Y direction (second horizontal direction) on the first edge region 130E1.

The fourth connection pads 141 are disposed on the first edge region 140E1 of the active surface 140F of the fourth semiconductor die 140. In another example embodiment, the connection pads (fourth connection pads 141 in FIG. 1) of the Nth semiconductor die (fourth semiconductor die 140 in FIG. 1) positioned at the top of the semiconductor stack S may be disposed on any region on the active surface of the Nth semiconductor die (fourth semiconductor die 140 in FIG. 1). Each of the bonding pad stacks 151S on the fourth semiconductor die 140 is disposed on a corresponding one of the fourth connection pads 141. The fourth connection pads 141 and the bonding pad stacks 151S on the fourth semiconductor die 140 are arranged in a line in the Y direction (second horizontal direction) on the first edge region 140E1.

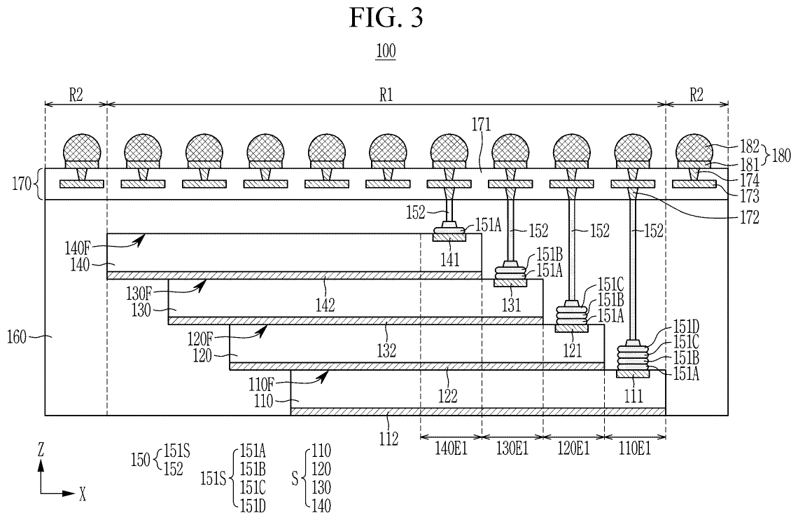

FIG. 3 is a cross-sectional view illustrating a semiconductor package 100 according to an example embodiment.

Referring to FIG. 3, depending on which semiconductor die the vertical wires 150 are disposed on among the first through N semiconductor die (the first through fourth semiconductor die (110, 120, 130, 140) in FIG. 3), the number of bonding pads 151 included on the vertical wires 150 may vary. On each of the first to Nth semiconductor dies (first to fourth semiconductor dies 110, 120, 130, and 140 in FIG. 3), the number of bonding pads 151 included in each of the vertical wires 150 may be the same across the vertical wires 150. For example, the vertical wires 150 on the first semiconductor die 110 may each include four bonding pads 151 (e.g., 151A, 151B, 151C and 151D), the vertical wires 150 on the second semiconductor die 120 may each include three bonding pads 151 (e.g., 151A, 151B and 151C), the vertical wires 150 on the third semiconductor die 130 may each include two bonding pads 151 (e.g., 151A and 151B), and the vertical wires 150 on the fourth semiconductor die 140 may each include one bonding pad 151 (e.g., 1151A).

The number of bonding pads 151 included in each of the vertical wires 150 may decrease from the vertical wires 150 on the first semiconductor die 110 to the vertical wires 150 on the Nth semiconductor die (the fourth semiconductor die 140 in FIG. 3). In some example embodiments, the number of bonding pads 151 included in each of the vertical wires 150 on the first semiconductor die 110 may be greater than the number of bonding pads 151 included in each of the vertical wires 150 on the remaining semiconductor die. As one moves from a lower semiconductor die to an upper semiconductor die within a semiconductor stack S, the length of the vertical wires 150 connected to each semiconductor die becomes shorter, the aspect ratio of the vertical wires 150 decreases, and the alignment error between the vertical wires 150 and the connection members 182 connected to the vertical wires 150 decreases. Therefore, the number of bonding pads 151 of the semiconductor die positioned in the upper portion may be designed to be smaller than the number of bonding pads 151 of the semiconductor die positioned in the lower portion.

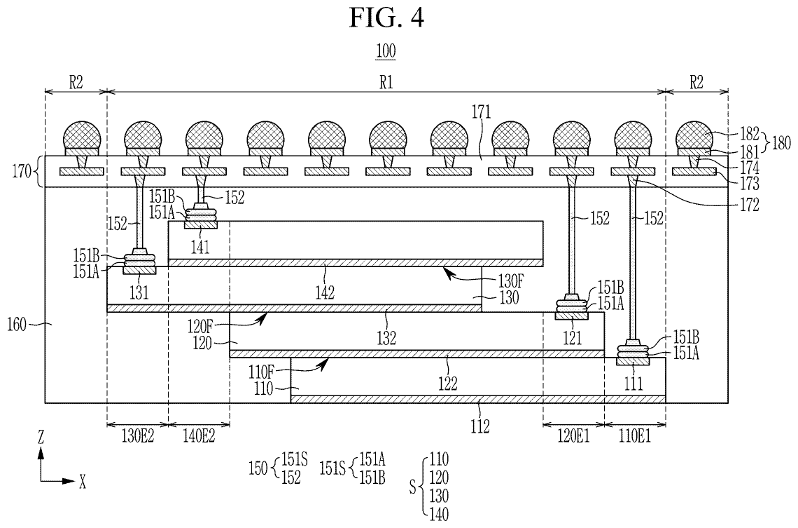

FIG. 4 is a cross-sectional view illustrating a semiconductor package 100 according to an example embodiment.

Referring to FIG. 4, the first to Nth semiconductor dies of the semiconductor stack S may be arranged to have an offset in the X direction (e.g., first horizontal direction) or a direction opposite to the X direction, respectively. Each of the first to Nth semiconductor dies may include a first edge region on the active surface and a second edge region opposite to the first edge region on the active surface. The connection pads may be arranged in the first edge region or the second edge region. The connection pads may be arranged in a row along the first edge region or the second edge region. The second edge region of any semiconductor die is defined as a region opposite to the first edge region.

For example, the second semiconductor die 120 is arranged to have an offset in a direction opposite to the X direction (first horizontal direction) from the first semiconductor die 110. By this offset, the first connection pads 111 of the first semiconductor die 110 are exposed on the first edge 110E1, and each of the first connection pads 111 may be connected to a corresponding one of the vertical wires 150. The third semiconductor die 130 is disposed to have an offset in a direction opposite to the X direction (first horizontal direction) from the second semiconductor die 120. Due to the offset, the second connection pads 121 of the second semiconductor die 120 are exposed on the first edge 120E1, and each of the second connection pads 121 may be connected to a corresponding one of the vertical wires 150. The fourth semiconductor die 140 is disposed to have an offset from the third semiconductor die 130 in the moving direction of the X direction (first horizontal direction). By this offset, the third connection pads 131 of the third semiconductor die 130 are exposed on the second edge region 130E2 of the third semiconductor die 130, and each of the third connection pads 131 may be connected to a corresponding one of the vertical wires 150. The third connection pads 131 may be arranged in a row along the second edge region 130E2. The second edge region 130E2 of the third semiconductor die 130 is a portion not covered by the fourth semiconductor die 140 on the active surface 130F of the third semiconductor die 130 and is defined as a region opposite to the first edge region 130E1 (in FIG. 3) of the third semiconductor die 130.

The fourth connection pads 141 of the fourth semiconductor die 140 may be positioned on the second edge region 140E2 of the fourth semiconductor die 140, but are not limited thereto. The second edge region 140E2 of the fourth semiconductor die 140 may be defined as a region from the side surface of the fourth semiconductor die 140 to a desired (or alternatively, predetermined) distance. The second edge region 140E2 of the fourth semiconductor die 140 may be defined as a region of the fourth semiconductor die 140 corresponding to a region in which the second edge region 130E2 of the third semiconductor die 130 is positioned.

According to the present disclosure, the first to Nth semiconductor dies of the semiconductor stack S may be arranged to have an offset in the X direction (first horizontal direction) or a direction apposite to the X direction, and the first to fourth connection pads 111, 121, 131, and 141 may be distributed and arranged in the semiconductor package 100 according to the arrangement of the first to Nth semiconductor dies. Thus, it is possible to reduce the alignment error between the vertical wire connected to the first to fourth connection pads (111, 121, 131, and 141) and the connection member connected to the vertical wire.

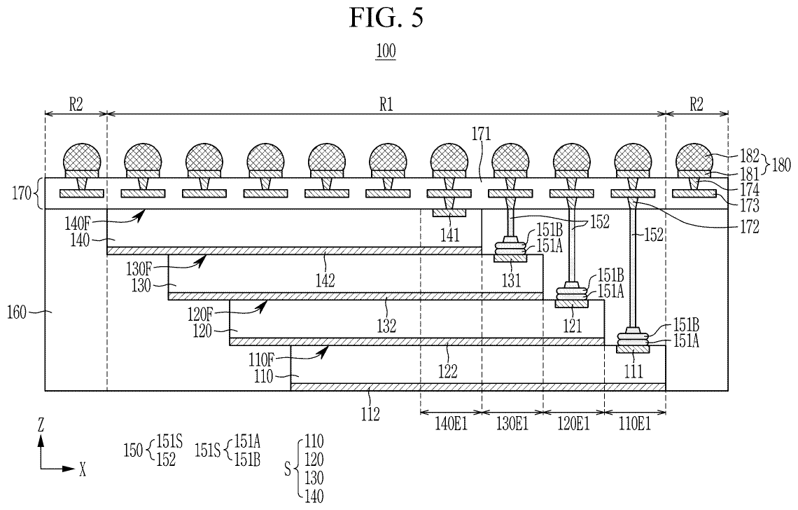

FIG. 5 is a cross-sectional view illustrating a semiconductor package 100 according to an example embodiment.

Referring to FIG. 5, an Nth semiconductor die (the fourth semiconductor die 140 in FIG. 5) positioned at the top of the semiconductor stack S may be in contact with the redistribution structure 170. The Nth semiconductor die 140 (the fourth semiconductor die 140 in FIG. 5) may be electrically connected to the redistribution structure 170 through a connection pad (the fourth connection pad 141 in FIG. 5) without a vertical wire.

According to the present disclosure, by combining an electrical connection using a vertical wire 150 and an electrical connection without a vertical wire 150, a path for routing signals and power may be efficiently implemented and the size of the semiconductor package 100 may be reduced.

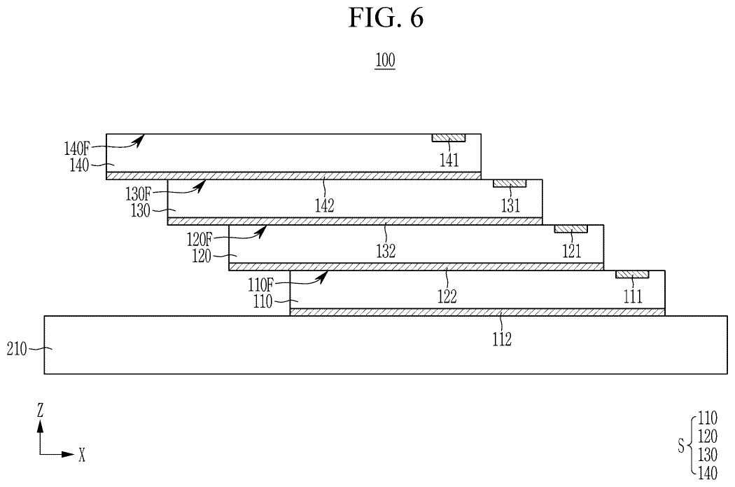

FIGS. 6 to 21 are cross-sectional views illustrating a method for manufacturing the semiconductor package 100 of FIG. 1.

FIG. 6 is a cross-sectional view illustrating a step of forming a semiconductor stack S on a carrier 210.

Referring to FIG. 6, a carrier 210 is provided. The carrier 210 may include a silicon-based material such as glass or silicon oxide, an organic material, other materials such as aluminum oxide, or any combination of these materials. In addition, the first to fourth semiconductor dies (110, 120, 130, 140) are sequentially stacked on the carrier 210 using each of the first to fourth adhesive members (112, 122, 132, 142). The first to fourth semiconductor dies (110, 120, 130, 140) are stacked with offsets in the X direction (first horizontal direction) so that each of the first to fourth connection pads (111, 121, 131, 141) is exposed.

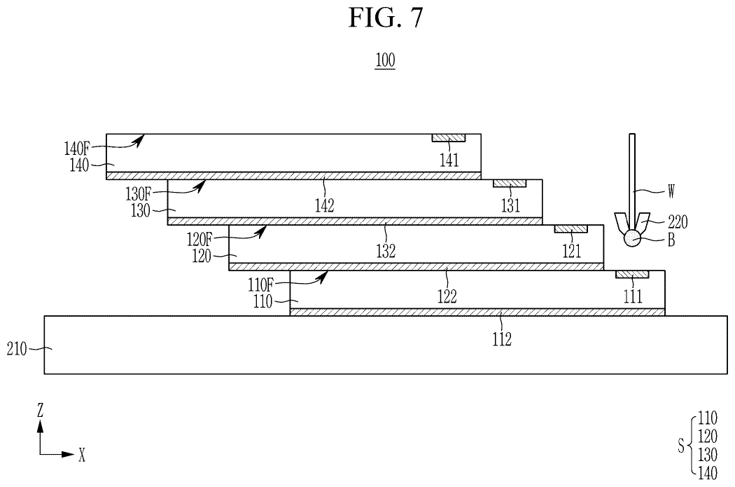

FIG. 7 is a cross-sectional view illustrating a step of aligning a capillary 220 on the first connection pad 111.

Referring to FIG. 7, the capillary 220 is aligned on the first connection pad 111, and one end of the wire W is formed into a ball B shape using the capillary 220. In an example embodiment, the ball B may be formed by applying heat to the tip of the capillary 220 or may be formed by applying a spark to one end of the wire W.

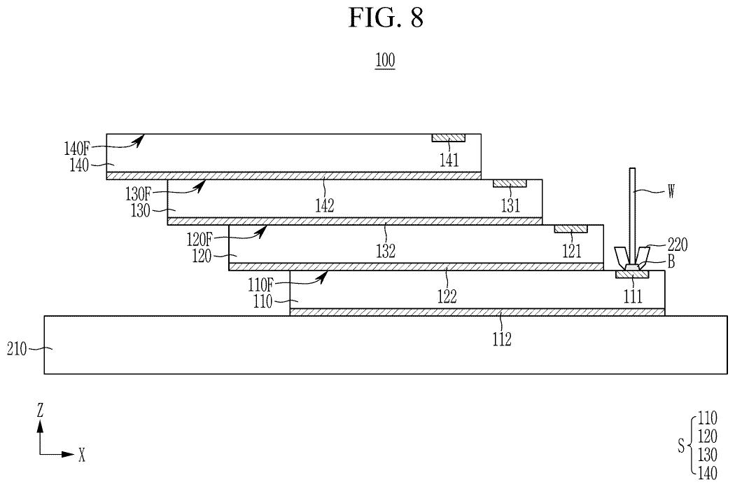

FIG. 8 is a cross-sectional view illustrating a step of bonding the ball B onto the first connection pad 111.

Referring to FIG. 8, the ball B is bonded onto the first connection pad 111 using a capillary 220. In an example embodiment, the ball B may be bonded by applying heat to the capillary 120, applying pressure to the capillary 220, or applying ultrasonic vibration to the capillary 220 to compress the first connection pad 111.

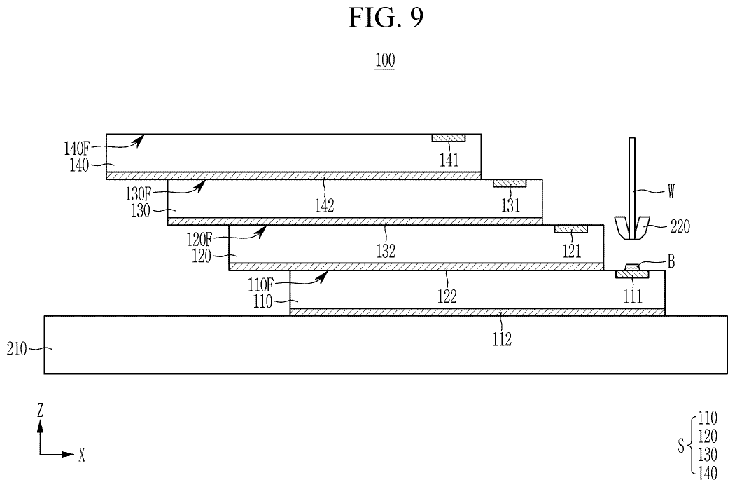

FIG. 9 is a cross-sectional view illustrating a step of separating the capillary 220 from the ball B.

Referring to FIG. 9, the wire W is cut from the ball B, and the capillary 220 is separated from the ball B.

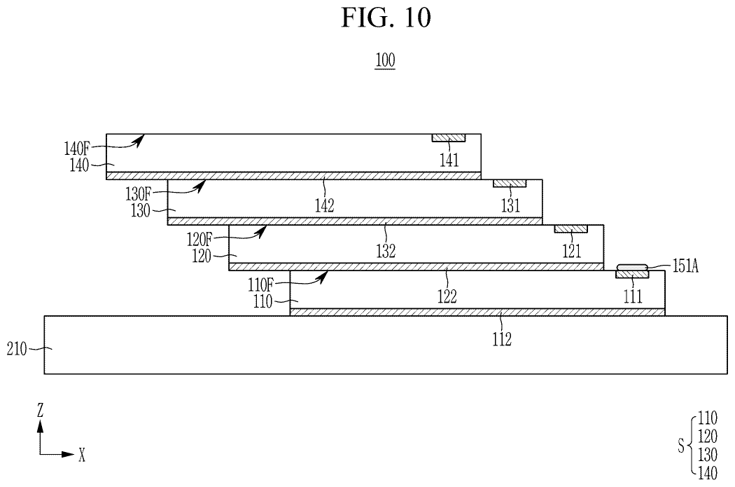

FIG. 10 is a cross-sectional view illustrating the step of forming the first bonding pad 151A.

Referring to FIG. 10, the first bonding pad 151A is formed by pressing the ball B.

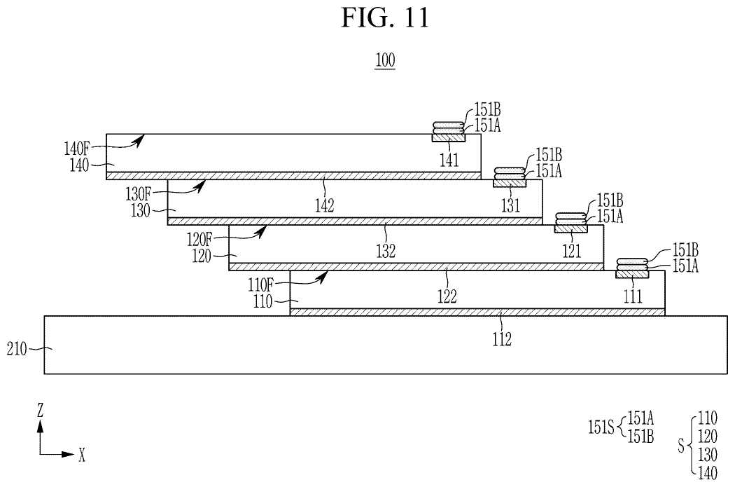

FIG. 11 is a cross-sectional view illustrating a step of forming a bonding pad stack 151S on the first to fourth connection pads (111, 121, 131, 141).

Referring to FIG. 11, a bonding pad stack 151S including bonding pads 151 (e.g., 151A and 151B) is formed on the first to fourth connection pads (111, 121, 131, 141) by repeating steps of FIGS. 7 to 10.

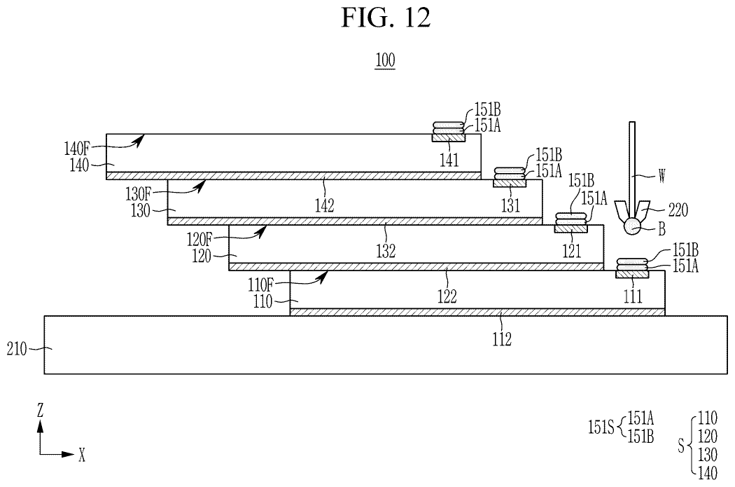

FIG. 12 is a cross-sectional view illustrating a step of aligning the capillary 220 on the bonding pad stack 151S.

Referring to FIG. 12, the capillary 220 is aligned on the bonding pad stack 151S on the first connection pad 111, and one end of the wire W is formed into a ball B shape using the capillary 220. In an example embodiment, the ball B may be formed by applying heat to the tip of the capillary 220 or may be formed by applying a spark to one end of the wire W.

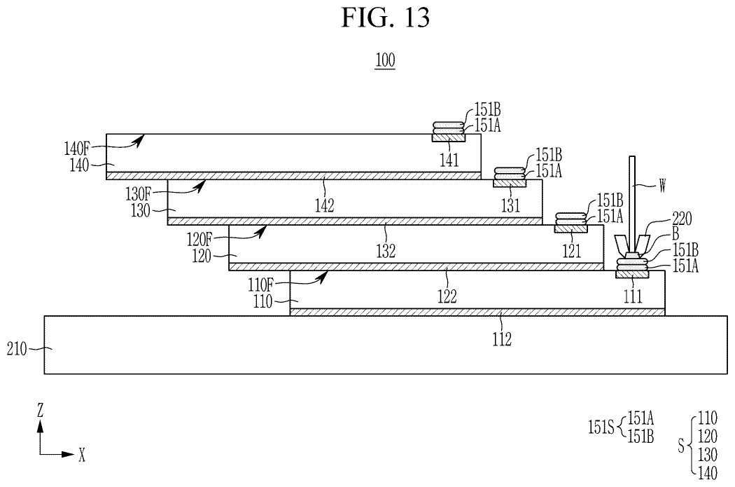

FIG. 13 is a cross-sectional view illustrating a step of bonding the ball B onto the bonding pad stack 151S on the first connection pad 111.

Referring to FIG. 13, the ball B is bonded onto the bonding pad stack 151S including the bonding pads 151 using the capillary 220. In one example embodiment, the ball B may be bonded by applying heat to the capillary 220, applying pressure to the capillary 220, or applying ultrasonic vibration to the capillary 220 and compressing it on the bonding pad stack 151S.

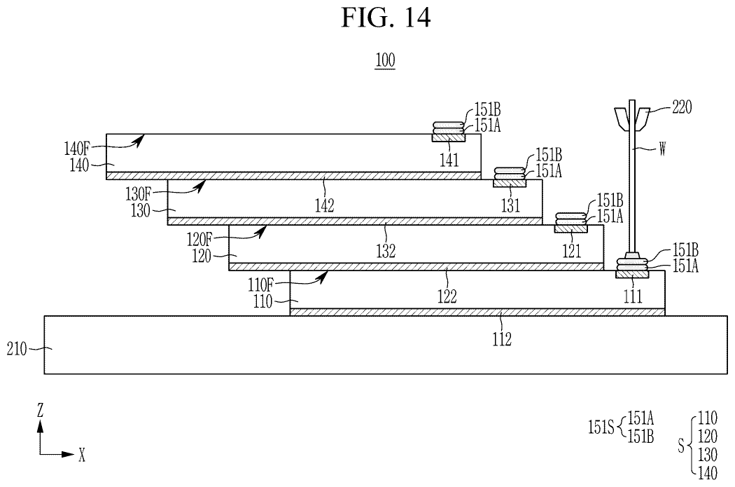

FIG. 14 is a cross-sectional view illustrating the step of pulling the wire W.

Referring to FIG. 14, the wire W pressed into the bonding pad stack 151S is pulled. The capillary 220 is raised by a desired (or alternatively, predetermined) distance so that the end of the wire 152 of the vertical wire 150 can be bonded to the redistribution structure 170. The end of the wire 152 corresponds to a portion opposite to the ball B pressed into the bonding pad stack 151S.

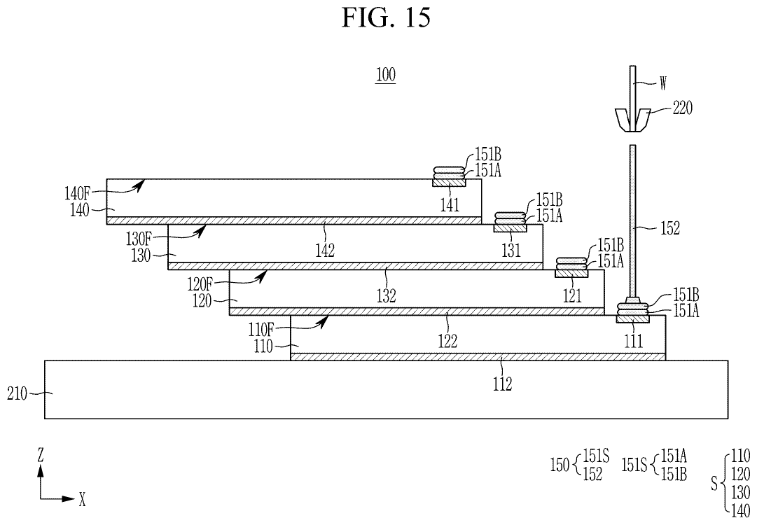

FIG. 15 is a cross-sectional view illustrating a step of forming a vertical wire 150 by cutting the wire W.

Referring to FIG. 15, the vertical wire 150 is formed by cutting the wire W. In an example embodiment, the width of the wire 152 may be about 10 μm to about 100 μm. In one example embodiment, the height of the vertical wire 150 may be about 40 μm to about 800 μm.

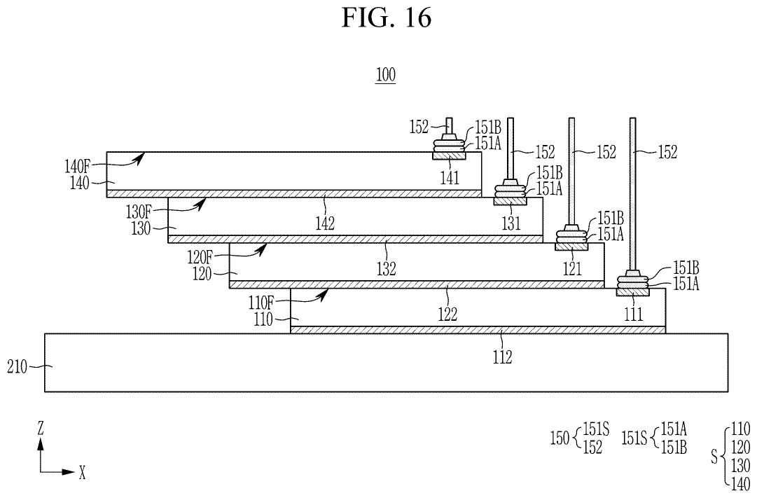

FIG. 16 is a cross-sectional view illustrating a step of forming a vertical wire 150 on a bonding pad stack 151S on the first to fourth connection pads 111, 121, 131, and 141.

Referring to FIG. 16, a vertical wire 150 is formed on the bonding pad stack 151S on each of the first to fourth connection pads (111, 121, 131, 141) by repeating steps of FIGS. 12 to 15.

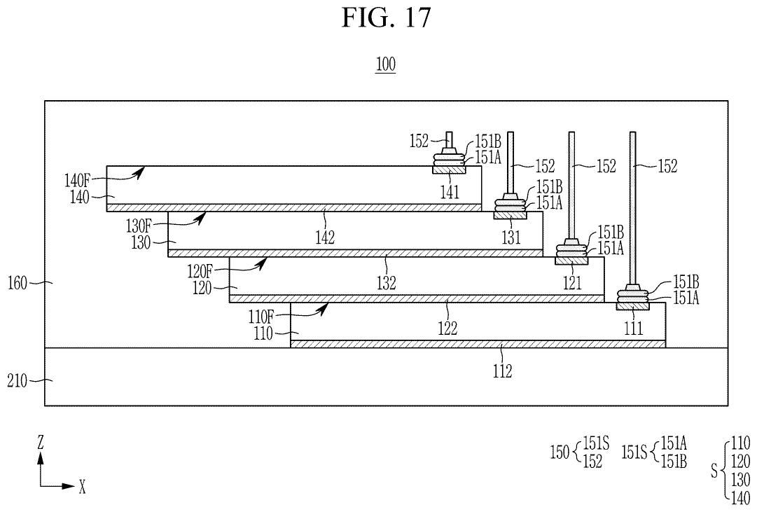

FIG. 17 is a cross-sectional view illustrating a step of molding the semiconductor stack S and the vertical wires 150 on the carrier 210.

Referring to FIG. 17, the semiconductor stack S and the vertical wires 150 are molded with a molding member 160 on the carrier 210. As an example embodiment, the molding process with the molding member 160 may include a compression molding process or a transfer molding process. In one example embodiment, the molding member 160 may include an epoxy molding compound (EMC).

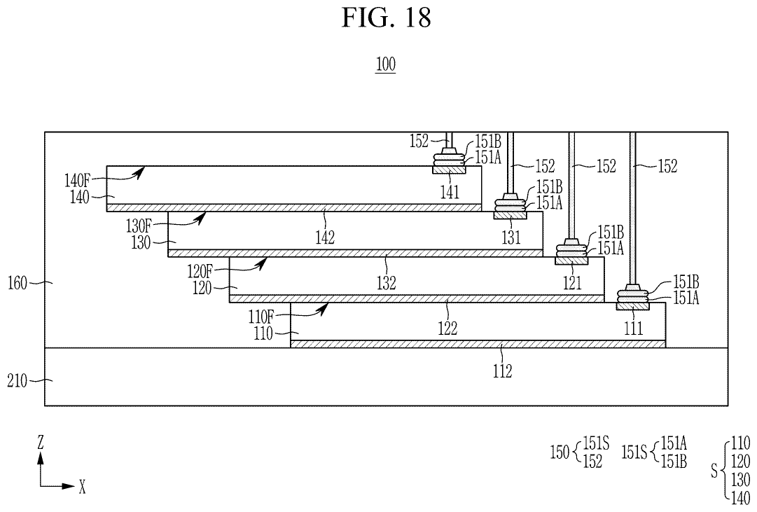

FIG. 18 is a cross-sectional view illustrating a step of performing a chemical mechanical planarization (CMP) process on the molding member 160.

Referring to FIG. 18, a chemical mechanical planarization (CMP) process is performed to planarize the upper surface of the molding member 160 to reduce or adjust the level of the upper surface of the molding member 160. After performing a chemical mechanical planarization (CMP) process, the ends of the wires 152 of each of the vertical wires 150 are exposed.

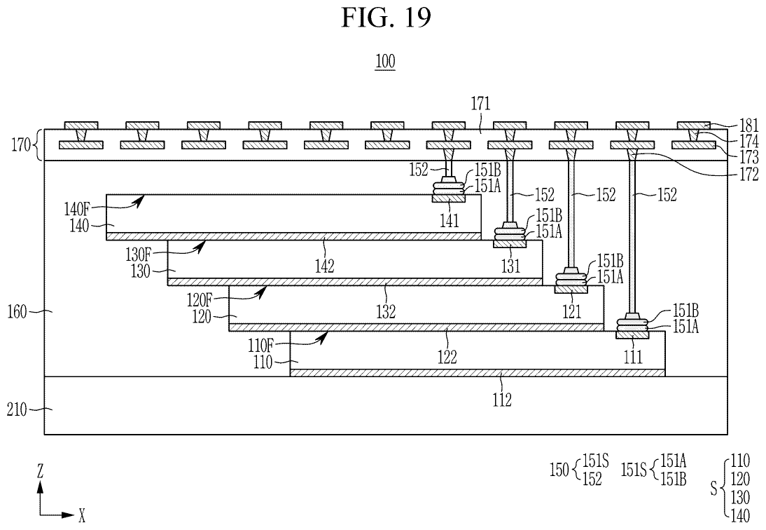

FIG. 19 is a cross-sectional view illustrating a step of forming the redistribution structure 170 on the molding member 160.

Referring to FIG. 19, a dielectric 171 is formed on the molding member 160 and on the vertical wires 150. In one example embodiment, the dielectric 171 may include a photosensitive dielectric (PID) used in a redistribution process. In an example embodiment, the photosensitive dielectric (PID) may include a polyimide-based photosensitive polymer, a novolac-based photosensitive polymer, a polybenzoxazole, a silicon-based polymer, an acrylate-based polymer, or an epoxy-based polymer. In one example embodiment, the dielectric 171 may be formed by performing a spin coating process.

After forming the dielectric 171, the dielectric 171 is selectively etched to form via holes, and the first redistribution vias 172 are formed by filling the via holes with a conductive material. After forming the first redistribution vias 172, a dielectric 171 is further formed on the first redistribution vias 172 and the dielectric 171, and the additionally formed dielectric 171 is selectively etched to form openings, and redistribution lines 173 are formed by filling the openings with a conductive material. After forming the redistribution lines 173, the dielectric 171 is further formed on the redistribution lines 173 and the dielectric 171, the additional dielectric 171 is selectively etched to form via holes, and the second redistribution vias 174 are formed by filling the via holes with a conductive material. In an example embodiment, the first redistribution vias 172, the redistribution lines 173, and the second redistribution vias 174 may each include at least one of copper, aluminum, tungsten, nickel, gold, tin, titanium, or alloys thereof. In an example embodiment, the first redistribution vias 172, the redistribution lines 173, and the second redistribution vias 174 may be formed by performing a sputtering process, respectively. In another example embodiment, the first redistribution vias 172, the redistribution lines 173, and the second redistribution vias 174 may be formed by forming a seed metal layer and then performing an electroplating process.

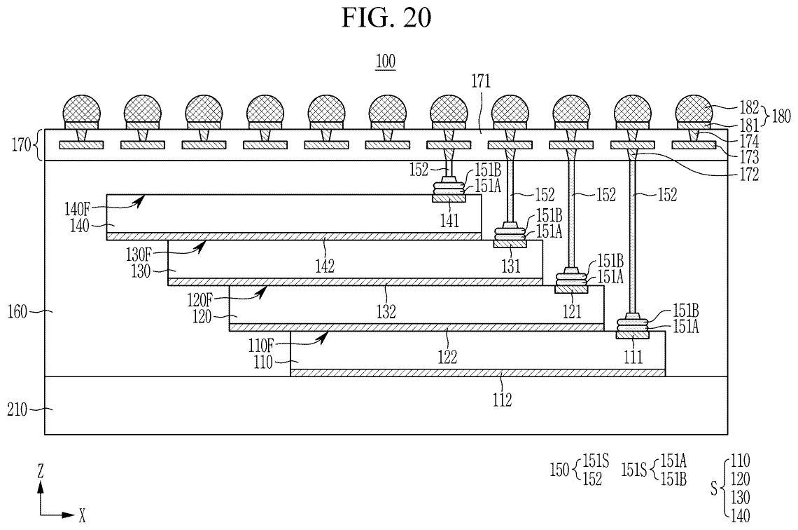

FIG. 20 is a cross-sectional view illustrating a step of forming a connection structure 180 on the redistribution structure 170.

Referring to FIG. 20, a connection structure 180 is formed on the redistribution structure 170. A conductive pad 181 is formed on each of the second redistribution vias 174 of the redistribution structure 170. In an example embodiment, the conductive pad 181 may include at least one of copper, nickel, zinc, gold, silver, platinum, palladium, chromium, titanium, or alloys thereof. In one example embodiment, the conductive pad 181 may be formed by performing a sputtering process, or an electroplating process after forming a seed metal layer. Thereafter, a connection member 182 is formed on each of the conductive pads 181. In an example embodiment, the connection member 182 may include at least one of tin, silver, lead, nickel, copper, or alloys thereof.

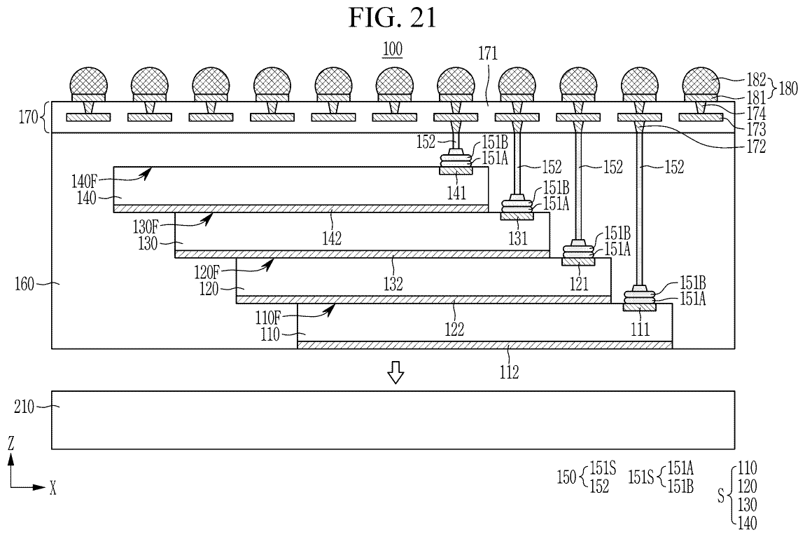

FIG. 21 is a cross-sectional view illustrating a step of removing the carrier 210.

Referring to FIG. 21, the carrier 210 is removed from the semiconductor stack S and the molding member 160.

Although some example embodiment of the present disclosure has been described above, the present disclosure is not limited thereto, and it is possible to perform various modifications within the scope of the claims, the detailed description of the disclosure, and the accompanying drawings, and it is natural to fall within the scope of the present disclosure.

What is claimed is:

1. A semiconductor package comprising:
a semiconductor stack comprising a first to Nth semiconductor dies, N being a natural number of 2 or more, each of the first to Nth semiconductor dies including a plurality of connection pads on a first surface, the first to Nth semiconductor dies being sequentially stacked so that the plurality of connection pads are exposed; and
a plurality of vertical wires on each of the first to Nth semiconductor dies, each of the plurality of vertical wires being connected to a corresponding one of the plurality of connection pads,
wherein each of the plurality of vertical wires comprises
a plurality of bonding pads stacked on each of the plurality of connection pads, and
a wire on the plurality of bonding pads.

2. The semiconductor package of claim 1, wherein each of the first to Nth semiconductor dies has an offset from an adjacent one from among the first to Nth semiconductor dies in a first horizontal direction.

3. The semiconductor package of claim 1, wherein
each of the first to Nth semiconductor dies comprises
a first edge region on the first surface, and
a second edge region opposite to the first edge region on the first surface, and
the plurality of connection pads are arranged in the first edge region or the second edge region.

4. The semiconductor package of claim 3, wherein the plurality of connection pads are arranged in a row along the first edge region or the second edge region.

5. The semiconductor package of claim 1, wherein
the semiconductor stack further comprises a plurality of adhesive members, and
the first to Nth semiconductor dies die alternate with the plurality of adhesive members.

6. The semiconductor package of claim 1, wherein the first surface is an active surface.

7. The semiconductor package of claim 1, wherein a number of the plurality of bonding pads included in each of the plurality of vertical wires is same.

8. The semiconductor package of claim 1, wherein a number of the plurality of bonding pads included in each of the plurality of vertical wires is same in each of the first to Nth semiconductor dies.

9. The semiconductor package of claim 8, wherein the number of the plurality of bonding pads included in each of the plurality of vertical wires is different by the first to Nth semiconductor dies.

10. The semiconductor package of claim 1, wherein a number of the plurality of bonding pads included in each of the plurality of vertical wires decreases from the plurality of vertical wires on the first semiconductor die to the plurality of vertical wires on the Nth semiconductor die.

11. The semiconductor package of claim 1, wherein a number of the plurality of bonding pads included in each of the plurality of vertical wires on the first semiconductor die is greater than a number of the plurality of bonding pads included in each of the plurality of vertical wires on the second to Nth semiconductor dies.

12. The semiconductor package of claim 1, wherein each of the plurality of vertical wires on the first semiconductor die has an aspect ratio from 1:5 to 1:15, the aspect ratio being a ratio of a diameter of the wire included in each of the plurality of vertical wires to a height of the each of the plurality of vertical wires.

13. A semiconductor package comprising:
a semiconductor stack comprising a first to Nth semiconductor dies, where N is a natural number of 2 or more, each of the first to Nth semiconductor dies including a plurality of connection pads on a first surface, the first to Nth semiconductor dies being sequentially stacked so that the plurality of connection pads are exposed; and
a plurality of vertical wires on each of the first to (N−1)th semiconductor dies, each of the plurality of vertical wires being connected to a corresponding one of the plurality of connection pads,
a molding member covering the first to Nth semiconductor dies and the plurality of vertical wires;
a redistribution structure on the molding member; and
a plurality of connection members on the redistribution structure,
wherein each of the plurality of vertical wires comprises
a plurality of bonding pads stacked on each of the plurality of connection pads, and
a wire on the plurality of bonding pads.

14. The semiconductor package of claim 13, wherein the Nth semiconductor die is in contact with the redistribution structure.

15. The semiconductor package of claim 13, wherein
the plurality of vertical wires are on the Nth semiconductor die, and
the Nth semiconductor die is spaced apart from the redistribution structure.

16. The semiconductor package of claim 15, wherein
a first end of the wire is in contact with an uppermost bonding pad among the plurality of bonding pads, and
a second end of the wire is in contact with the redistribution structure.

17. The semiconductor package of claim 13, wherein the plurality of connection members are in a fan-in region and a fan-out region.

18. The semiconductor package of claim 17, wherein
the redistribution structure comprises a dielectric material and a plurality of redistribution lines within the dielectric material, and
a plurality of connection members in the fan-out region are electrically connected to the first to Nth semiconductor dies through the plurality of redistribution lines and the plurality of vertical wires.

19. A semiconductor package manufacturing method comprising:
sequentially stacking, on a carrier, first to Nth semiconductor dies each including a plurality of connection pads on a first surface thereof, such that the plurality of connection pads are exposed, where N is a natural number greater than or equal to 2, and
forming a plurality of vertical wires on the first to Nth semiconductor dies,
wherein the forming the plurality of vertical wires on the first to Nth semiconductor dies comprises
stacking a plurality of bonding pads on each of the plurality of connection pads, and
vertically forming a wire on the plurality of bonding pads.

20. The semiconductor package manufacturing method of claim 19, further comprising:
molding the first to Nth semiconductor dies and the plurality of vertical wires with a molding material.
